(19) United States
(12) Patent Application Publication
(10) Pub. No.: US 2022/0237349 A1
(43) Pub. Date: Jul. 28, 2022

(54) MODEL GENERATION DEVICE, SYSTEM, PARAMETER CALCULATION DEVICE, MODEL GENERATION METHOD, PARAMETER CALCULATION METHOD, AND RECORDING MEDIUM

(71) Applicant: NEC Corporation, Minato-ku, Tokyo (JP)

(72) Inventors: Keiichi KISAMORI, Tokyo (JP); Keisuke YAMAZAKI, Tokyo (JP)

(73) Assignee: NEC Corporation, Minato-ku, Tokyo (JP)

(21) Appl. No.: 17/611,959

(22) PCT Filed: May 21, 2020
(86) PCT No.: PCT/JP2020/020103

§ 371 Date: Nov. 17, 2021

(30) Foreign Application Priority Data
May 22, 2019 (JP) 2019-096326

(51) Int. Cl. G06F 30/27

(52) U.S. Cl. CPC G06F 30/27

(57) ABSTRACT

A model generation device includes: a model generation means for generating a second model indicating a relationship between a parameter included in a first model and a sample, the first model indicating a relationship between the sample and a label of the sample.

### TECHNICAL FIELD

The present invention relates to a model generation device, a system, a parameter calculation device, a model generation method, a parameter calculation method, and a recording medium.

### BACKGROUND ART

Patent Document 1 discloses a simulation device that applies operation status prediction data learned preliminarily using meteorological data and the like to the execution of training simulation by a simulator, for the purpose of realizing a simulation based on the actual situation.

### PRIOR ART DOCUMENTS

### Patent Documents

[Patent Document 1] Japanese Unexamined Patent Application, First Publication No. 2008-180784

### SUMMARY OF THE INVENTION

### Problem to be Solved by the Invention

In the case where meaning can be given to parameters of a model used in a simulator, it is conceivable to use the values of the parameters for analyzing an analysis target. For example, it is conceivable to acquire parameter values that enable accurate simulation of the analysis target and estimate the state of the analysis target using the obtained parameter values. However, the process of acquiring appropriate parameter values includes many processes. Therefore, the length of time required for the processing is long.

An example object of the present invention is to provide a model generation device, a system, a parameter calculation device, a model generation method, a parameter calculation method, and a recording medium.

### Means for Solving the Problem

According to a first example aspect of the present invention, a model generation device includes: a model generation means for generating a second model indicating a relationship between a parameter included in a first model and a sample, the first model indicating a relationship between the sample and a label of the sample.

According to a second example aspect of the present invention, a parameter calculation device includes: a model execution means for calculating a parameter of a first model regarding a given sample by applying a second model to the given sample, the first model indicating a relationship between a sample and a label of the sample, the second model indicating a relationship between a parameter included in the first model and the sample.

According to a third example aspect of the present invention, a model generation method executed by a computer includes: generating a second model indicating a relationship between a parameter included in a first model and a sample, the first model indicating a relationship between the sample and a label of the sample.

According to a fourth example aspect of the present invention, a parameter calculation method execute by a computer includes: a model execution means for calculating a parameter of a first model regarding a given sample by applying a second model to the given sample, the first model indicating a relationship between a sample and a label of the sample, the second model indicating a relationship between a parameter included in the first model and the sample.

According to a fifth example aspect of the present invention, a recording medium storing a program for causing a computer to execute a function of: generating a second model indicating a relationship between a parameter included in a first model and a sample, the first model indicating a relationship between the sample and a label of the sample.

According to a sixth example aspect of the present invention, a recording medium storing a program for causing a computer to execute a function of: calculating a parameter of a first model regarding a given sample by applying a second model to the given sample, the first model indicating a relationship between a sample and a label of the sample, the second model indicating a relationship between a parameter included in the first model and the sample.

### Effect of the Invention

According to an example embodiment of the present invention, data that can be used for analyzing an analysis target can be obtained in a comparatively short period of time.

### BRIEF DESCRIPTION OF THE DRAWINGS

FIG. 1 is a schematic configuration diagram showing a device configuration example of a prediction system according to an example embodiment.

FIG. 2 is a schematic block diagram showing an example of a functional configuration of a model generation device according to the example embodiment.

FIG. 3 is a diagram showing an example of a production line that serves as a target of the prediction system according to the example embodiment.

FIG. 4 is a diagram showing an example of a configuration of the model generation device according to an example embodiment.

FIG. 5 is a diagram showing an example of a configuration of a parameter calculation device according to an example embodiment.

FIG. 6 is a diagram showing an example of processing in a model generation method according to an example embodiment.

FIG. 7 is a diagram showing an example of processing in a parameter calculation method according to an example embodiment.

FIG. 8 is a schematic block diagram showing a configuration of a computer according to at least one example embodiment.

### EXAMPLE EMBODIMENT

Hereinafter, example embodiments of the present invention are described. However, the present invention within the scope of the claims is not limited by the following example embodiments. Furthermore, all the combinations of features described in the example embodiments may not be essential for the solving means of the invention.

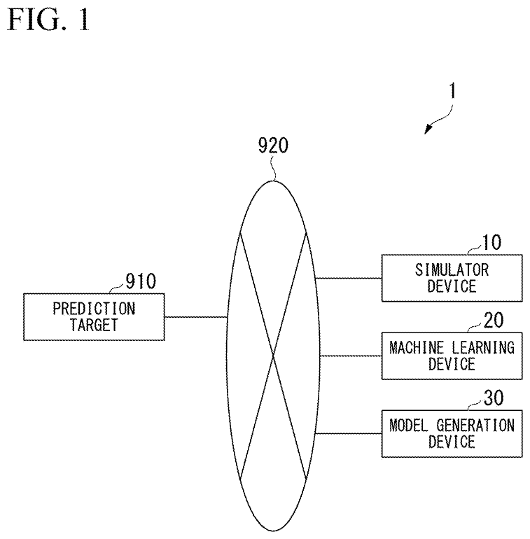

FIG. 1 is a schematic configuration diagram showing a device configuration example of a prediction system according to the example embodiment of the present invention. In the configuration shown in FIG. 1, a prediction system 1 includes a simulator device 10, a machine learning device 20, and a model generation device 30. Moreover, the simulator device 10, the machine learning device 20, the model generation device 30, and a prediction target 910 communicate with each other via a communication network 920.

The prediction system 1 predicts the behavior or state of the prediction target 910. Furthermore, the prediction system 1 acquires information that aids the analysis of the behavior or state of the prediction target 910.

The prediction target 910 may be any prediction target that enables simulation of the behavior or state thereof, and is not limited to a specific prediction target.

For example, in the case where the prediction target 910 is a physical distribution system of a courier company or the like, the prediction system 1 may, on the basis of the arrangement of resources such as trucks and staff members as well as the distribution of goods to be delivered, predict the delivery status after a predetermined length of time such as three hours (the arrangement of resources and the distribution of goods to be delivered after the predetermined length of time), and may provide the user with the prediction result. In such a case, the values of input data are parameter values representing the arrangement of resources such as trucks and staff members, and parameter values representing the distribution of goods to be delivered. The values of the output data are parameter values representing the delivery status after a predetermined length of time. In addition, the prediction system 1 may provide the user with parameter values of a simulation model when the prediction is performed by a simulator. Moreover, the prediction system 1 may include parameters representing state values different from input data and output data (for example, parameters representing intermediate states, data representing the relationship between input data and output data).

The user can use the data from the prediction system 1 to analyze the delivery status such as whether or not the delivery status is favorable after a predetermined time, and if not, where a bottleneck is occurring.

Hereinafter, analysis of the behavior or state of the prediction target 910 is simply referred to as analysis of the prediction target 910. The above analysis of the delivery status corresponds to an example of the analysis of the prediction target 910.

The simulator device 10 simulates the behavior or state of the prediction target 910. The simulator device 10 uses a model including parameters as a simulation model for simulating the prediction target 910. The simulation model represents a process of calculating output data from input data. The simulation model may be, for example, a model that mathematically expresses the relationship between input data and output data, or a model that physically expresses an event between input and output.

The values to be set in the parameters are preliminarily defined with respect to the values of input data to the model for the simulator device 10, on the basis of the actual data in the prediction target 910. The simulator device 10 may automatically acquire the relationship between the values of input data and the parameter setting values by machine learning for example. Alternatively, a person (for example, the user of the prediction system 1) may preliminarily determine the parameter setting values for the values of the input data by executing a simulation or performing data analysis.

The simulation model of the simulator device 10 corresponds to an example of a first model. The simulator device 10 corresponds to an example of a parameter setting unit (parameter setting means).

The machine learning device 20 learns the behavior or state of the prediction target 910 (machine learning), and predicts the behavior or state of the prediction target 910, using the learning result. The machine learning device 20 may include a neural network for learning; however, the mechanism by which the machine learning device 20 performs machine learning is not limited to this example. The machine learning device 20 may learn using, for example, a model such as a support vector machine and a decision tree. The machine learning device 20 calculates the parameter values of the model so as to accurately calculate the output data values with respect to the input data values.

The model obtained by machine learning of the machine learning device 20 is called a machine learning model.

Comparing the prediction by the simulator device 10 and the prediction by the machine learning device 20, the prediction by the machine learning device 20 takes less amount of time than the prediction by the simulator device 10. This is because the calculation amount of machine learning is typically less than the calculation amount of simulation performed on the basis of a physical model. Meanwhile, a person (for example, the user) can analyze the basis of the prediction performed by the simulator device 10. In contrast to this, it is difficult for a person to analyze the basis of the prediction performed by the machine learning device 20.

For example, the parameters of a simulation model used by the simulator device 10 are physical quantities related to the actual prediction target 910, and the user can take advantage of the values for the analysis of the prediction target 910. On the other hand, in the case where the machine learning device 20 performs machine learning using a neural network, it is usually difficult to associate the weight (parameter value) in the neural network with an actual physical quantity.

The model generation device 30 acquires parameter values to be set in the simulation model for the simulator device 10 to perform a similar prediction on the basis of the input/output in the prediction performed by the machine learning device 20. Therefore, the model generation device 30 preliminarily learns the model that receives input of the input data for prediction and the prediction result obtained by the machine learning device 20 and outputs parameter values of the simulation model for acquiring the prediction result, from the input data. Hereinafter, the parameter values of the simulation model of the simulator device 10 for the simulator device 10 to output the same prediction result as the prediction result of the machine learning device 20 is referred to as the parameter values of the simulation model corresponding to the prediction result of the machine learning device 20. The prediction result from the simulator device 10 and the prediction result from the machine learning device 20 typically include errors. Therefore, in the present example embodiment, for errors within a predetermined range (for example, 1%, 5%, 7%, and so forth), prediction results are assumed matched even if there are errors in the prediction results. In the following, for convenience of explanation, even if an error within a predetermined range occurs in a prediction result, the prediction result will be described using the term “same” or “matching”.

Moreover, the model learned by the model generation device 30 is also referred to as a bridge model. The bridge model corresponds to an example of a second model. In other words, the bridge model is a model that represents the relationship between the parameter values calculated by the machine learning device 20 and the parameter values of the simulation model.

The model generation device 30 is configured, using a computer such as a personal computer (PC) or a workstation (WS).

The processing performed by the model generation device 30 is classified into a learning phase and a prediction phase. The model generation device 30 generates a bridge model in the learning phase. For example, the model generation device 30 acquires the bridge model and calculates the parameter values of the bridge model. Then, the model generation device 30 uses the model bridge in the prediction phase to acquire the parameter values of the simulation model corresponding to the prediction result of the machine learning device 20.

The model generation device 30 acquiring the parameter values of the simulation model enables the user to use the parameter values of the simulation model, for example, for the analysis of the prediction target 910 such as the analysis of the prediction result obtained by the machine learning device 20.

The model generation device 30 corresponds to an example of a parameter calculation device.

The communication network 920 mediates communication between the model generation device 30, the simulator device 10, the machine learning device 20, and the prediction target 910. The type of communication network 920 is not limited to a particular type. For example, the communication network 920 may be the Internet. Alternatively, the communication network 920 may be configured as a communication network of a dedicated line of the prediction system 1.

The method by which the prediction system 1 predicts the behavior or state of the prediction target 910 is not limited to a method performed by machine learning. Furthermore, the data acquired by the prediction system 1 for aiding the analysis of the prediction target 910 is not limited to the parameter values of the simulation model. For example, the prediction system 1 can be applied to various situations where the following conditions (1) and (2) are satisfied.

(1) As a method for predicting the behavior or state of the prediction target 910, a method is used in which it is difficult for a person to directly understand the basis of the prediction (from the parameter values of the prediction model and so forth).

(2) In the case where the data acquired by the prediction system 1 to aid the analysis of the prediction target 910 is supposed to be directly acquired (by simulation, analysis, or the like), it takes more time compared to acquiring the data using a bridge model or it is more difficult to directly acquire the data.

Hereunder, the data acquired by the prediction system 1 for aiding the analysis of the prediction target 910 is referred to as analysis aid data. The parameter values of the simulation model correspond to an example of the analysis aid data.

As will be described later, the model generation device 30 may generate a bridge model that outputs analysis data to the prediction input data without requiring the prediction results. In such a case, the bridge model is a model that represents the relationship between the input data and the parameter values of the simulation model.

Any two or more of the simulator device 10, the machine learning device 20, and the model generation device 30 may be integrated into a single device.

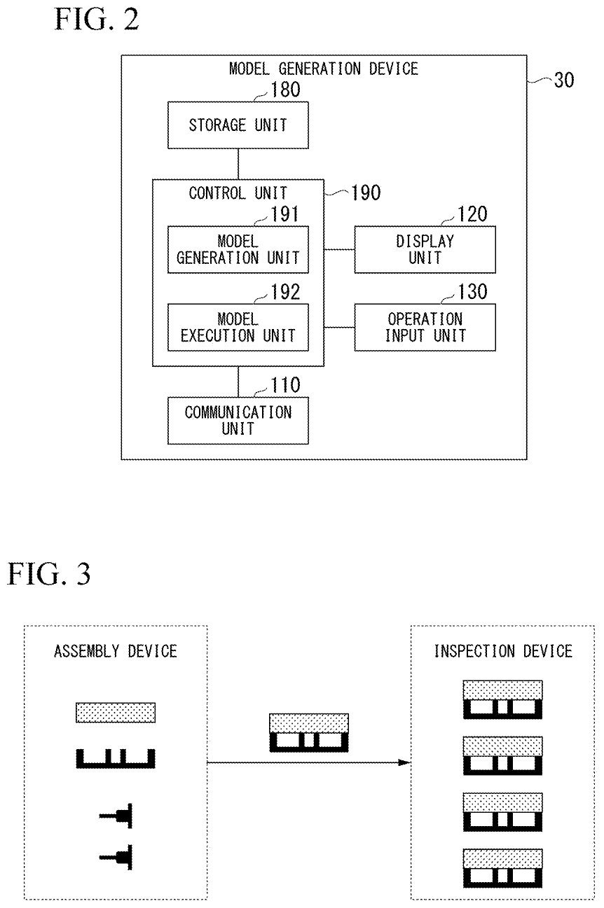

FIG. 2 is a schematic block diagram showing an example of a functional configuration of the model generation device 30. In the configuration shown in FIG. 2, the model generation device 30 includes a communication unit 110, a display unit 120, an operation input unit 130, a storage unit 180, and a control unit 190. The control unit 190 includes a model generation unit 191 and a model execution unit 192.

The communication unit 110 communicates with other devices. For example, the communication unit 110 receives a prediction result of the behavior or state of the prediction target 910 from the machine learning device 20.

The display unit 120 includes a display screen such as a liquid crystal panel or an LED (light emitting diode) panel, and displays various types of images. For example, the display unit 120 displays analysis aid data.

The operation input unit 130 includes input devices such as a keyboard and a mouse, and receives user operations. For example, the operation input unit 130 accepts a user operation instructing acquisition of analysis aid data.

The storage unit 180 stores various types of data. The storage unit 180 is configured using a storage device included in the model generation device 30.

The control unit 190 controls each unit of the model generation device 30 and executes various processes. Functions of the control unit 190 are executed by a CPU (central processing unit) included in the model generation device 30 reading out a program from the storage unit 180 and executing the program.

The model generation unit 191 generates a bridge model in the learning phase.

In the prediction phase, the model execution unit 192 acquires analysis aid data using the bridge model generated by the model generation unit 191. Specifically, the model execution unit 192 applies prediction input data to the bridge model to calculate the analysis aid data.

The device that executes the function of the model generation unit 191 (that is, the device that generates a bridge model) and the device that executes the function of the model execution unit 192 (that is, the device that acquires analysis aid data using the bridge model) may be configured as separate devices.

Generation of a bridge model by the model generation unit 191 will be further described.

Here, assuming that the following conditions (A) to (E) are satisfied, an example is described in which the machine learning device 20 performs machine learning for predicting the behavior or state of the prediction target 910, and the model generation device 30 generates a bridge model that outputs the parameter values of the simulation model of the simulator device 10.

(A) A simulation model for simulating the prediction target 910 exists. Moreover, a person can use the parameter values of the simulation model for the analysis of the prediction target 910.

(B) While the machine learning device 20 can sufficiently accurately predict the behavior or state of the prediction target 910, the values of the machine learning parameters of the machine learning device 20 cannot be used for the analysis of the prediction target 910.

(C) The calculation cost for the simulator device 10 to predict the behavior or state of the prediction target 910 in a simulation is higher than the calculation cost for the machine learning device 20 to perform a prediction using a machine learning result. In particular, the length of time required for the simulator device 10 to perform a prediction is longer than the length of time required for the machine learning device 20 to perform a prediction.

(D) There is a relationship between the values of the input data for predicting the behavior or state of the prediction target 910 and the values of the parameters of the simulation model of the simulator device 10.

(E) A sufficient length of time is available for offline calculation to acquire the relationship between the values of the input data for predicting the behavior or state of the prediction target 910 and the values of the parameters of the simulation model of the simulator device 10. Meanwhile, the length of time available for predicting the behavior or state of the prediction target 910 is limited.

A machine learning model of the machine learning device 20 is expressed as Equation (1).

$$\begin{matrix}[ Equation 1 ] & \\ y = {f}_{ml} ( x ; ξ ) & ( 1 )\end{matrix}$$

x is input data for prediction and includes dₓ real numbers. That is to say, x is an element of R^{dx}. “R” indicates a real space.

y is output data indicating a prediction result and includes d_{y} real numbers. That is to say, y is an element of R^{dy}.

ξ is a vector representation of a machine learning parameter value. The machine learning device 20 has d_{ξ} real-number parameters as machine learning parameters. That is to say, ξ is an element of R^{dξ}.

Moreover, a simulation performed by the simulator device 10 is expressed as Equation (2).

$$\begin{matrix}[ Equation 2 ] & \\ y = {f}_{sim} ( x ; θ ) & ( 2 )\end{matrix}$$

x and y are similar to those in the case of Equation (1). x corresponds to a sample example. y corresponds to an example of a label. The label here refers to data related to a sample. The label may be a class representing discrete information or a numerical value representing continuous information.

Ideally, the machine learning device 20 and the simulator device 10 output the same prediction result (output data y) for the same input data x. In the following, it is assumed that the difference in the output data y for the same input data x is sufficiently small and the output data y can be considered the same between the machine learning device 20 and the simulator device 10.

θ is a vector representation of a simulation model parameter value. The simulation model of the machine learning device 20 has do real-number parameters. That is to say, θ is an element of R^{dθ}.

The model generation unit 191 acquires expression in the RKHS (Reproducing Kernel Hilbert Space) for each of the function fₘₗ indicating the machine learning model of the machine learning device 20 and the function fₛᵢₘ indicating the simulation model of the simulator device 10. This process is referred to as preprocessing.

The model generation unit 191 acquires the function that receives the input of the function indicating the machine learning model of the machine learning device 20 and outputs the function of the simulation model of the simulator device 10. This process is referred to as actual processing.

In the preprocessing, upon receiving the input of {Xⁿₗ, Yⁿₗ, . . . , Xⁿ_{L}, Yⁿ_{L}}, the model generation unit 191 calculates {μ^{\hat{ },ml}ₗ, . . . , μ^{\hat{ },ml}_{L}} and {μ^{\hat{ },sim}ₗ, . . . , μ^{\hat{ },sim}_{L}}.

Here, it is assumed that the parameter value ξ of the machine learning model of the machine learning device 20 and the parameter value θ of the simulation model of the simulator device 10 change according to the changes in the state of the prediction target 910.

Xⁿₗ(l=1, . . . , L) is sample data of the input data x for prediction in a unit time in which the parameter values ξ and θ can be considered constant. Xₙₗ shows the distribution of x with n sample data. As mentioned above, x is an element of dₓ, and therefore, Xₙ₁ is indicated by n×dₓ real numbers. That is to say, xⁿ₁ is an element of R^{n×dx}.

Yⁿₗ (l=1, . . . , L) is sample data of the output data y indicating the prediction result obtained by the machine learning device 20 in a unit time in which the parameter values ξ and θ can be considered constant. Yₙₗ shows the distribution of y with n sample data. As mentioned above, y is an element of d_{y}, and therefore, Yₙₗ is indicated by n×d_{y} real numbers. That is to say, Yⁿₗ is an element of R^{n×dy}.

In the following, a case will be described in which the unit time in which the parameter values ξ and θ can be considered constant is one day. However, the unit time in which the parameter values ξ and θ can be considered constant is not limited to a particular length of time. For example, in the case where variation is comparatively likely in the state of the prediction target 910, the unit time in which the parameter values ξ and θ can be considered constant may be three hours.

μ^{\hat{ }, ml}ₗ(l=1, . . . , L) indicates a kernel mean of the machine learning model corresponding to a dataset {Xⁿₗ, Yⁿₗ}. The model corresponding to the data set {Xⁿₗ, Yⁿₗ} is a model that outputs y of the distribution indicated by Yⁿₗ for the input of x of the distribution indicated by Xⁿₗ. The superscript “\hat{ }” indicates an estimated value.

μ^{\hat{ },sim}ₗ(l=1, . . . , L) indicates a kernel mean of the simulation model corresponding to a dataset {Xⁿₗ, Yⁿₗ}.

The kernel means are indicated by points on the RKHS. As a method for the model generation unit 191 to calculate μ^{\hat{ },ml}ₗ and μ^{\hat{ },sim}ₗ, a method of kernel ABC (Kernel Approximate Bayesian Computation) can be used.

In the actual processing, the model generation unit 191 calculates T^{\hat{ }} on the basis of {μ^{\hat{ },ml}₁, . . . , μ^{\hat{ },ml}_{L}} and {μ^{\hat{ },sim}ₗ, . . . , μ^{\hat{ },sim}_{L}}. T^{\hat{ }} is an expression in the RKHS space of the function that outputs the simulation model μ^{\hat{ }, sim} upon receiving the input of the machine learning model μ^{\hat{ }, ml}.

The model generation unit 191 calculates T^{\hat{ }} on the basis of Equation (3).

$$\begin{matrix}[ Equation 3 ] & \\ {T}^{⋀} = arg {max}_{T} \{ \frac{1}{L} {\sum }_{l = 1}^{L} {‖ {μ}_{l}^{⋀ , sim} - T ( {μ}_{l}^{⋀ , ml} ) ‖}_{H}^{2} + λ {‖ T ‖}_{H}^{2} \} & ( 3 )\end{matrix}$$

Here, “λ” is a constant for regularization and “λ>0”. “H” indicates the RKHS space. ∥ ∥_{H} indicates the norm in the RKHS space. In the RKHS space, polynomial functions are indicated by points, and the similarity of functions can be calculated by the norm.

As shown by Σ₁=₁^{L}∥^{\hat{ }, sim}ₗ−T(μ^{\hat{ },sim}ₗ)∥_{H}² of Equation (3), T^{\hat{ }} is calculated so that the error from μ^{\hat{ },sim}ₗ is as small as possible when converting μ^{\hat{ },ml}ₗ using the function T.

λ∥T∥_{H}² in Equation (3) is a regularization term for preventing overlearning, and functions as a penalty term for the model becoming complex.

Next, the calculation of the parameter value of the simulation model by the model execution unit 192 will be further described.

Upon receiving an input of {Xⁿ_{L+1}, Yⁿ_{L+1}}, the model execution unit 192 calculates the parameter values of the simulation model corresponding to this {Xⁿ_{L+1}, Yⁿ_{L+1}}. The parameter values of the simulation model corresponding to {Xⁿ_{L+1}, Yⁿ_{L+1}} here are parameter values for the simulator device 10 to output Yⁿ_{L+1} to the input of the Xⁿ_{L+1}.

The model execution unit 192 calculates μ^{\hat{ },ml}_{L+1} on the basis of {Xⁿ_{L+1}, Yⁿ_{L+1}}, and applies the obtained μ^{\hat{ },ml}_{L+1} to T^{\hat{ }} to calculate μ^{\hat{ },sim}_{L+1}. The simulator device 10 calculates θ_{L+1} on the basis of the obtained μ^{\hat{ },sim}_{L+1}.

The method by which the model execution unit 192 calculates μ^{\hat{ },ml}_{L+1} on the basis of {Xⁿ_{L+1}, Yⁿ_{L+1}}, and the method by which the model generation unit 191 finds μ^{\hat{ },ml}ₗ on the basis of {Xⁿₗ, Yⁿₗ} can be the same.

Here, Gaussian Like Kernel κ is defined as in Equation (4) where μ and μ′ are both taken as functions in the RKHS space.

$$\begin{matrix}[ Equation 4 ] & \\ κ ( μ , {μ}^{′} ) = exp \{ - \frac{1}{2 {σ}_{μ}^{2}} {‖ μ - {μ}^{′} ‖}_{H}^{2} \} ∈ H & ( 4 )\end{matrix}$$

σ_{μ} is a constant indicating the width of the kernel κ, where “σ_{μ}>0”.

The calculation of μ^{\hat{ },sim}_{L+1} performed by the model execution unit 192 is expressed as Equation (5).

$$\begin{matrix}[ Equation 5 ] & \\ {μ}_{L + 1}^{⋀ , sim} - {T}^{⋀} ( {μ}_{L + 1}^{⋀ , ml} ) = {\sum }_{l = 1}^{L} {v}_{l} {μ}_{l}^{⋀ , sim} ∈ H & ( 5 )\end{matrix}$$

v₁ is expressed as v₁, . . . , v_{L} in Equation (6).

$$\begin{matrix}[ Equation 6 ] & \\ v = {( {v}_{1} , … , {v}_{L} )}^{T} ∈ {R}^{L} = {( G + λ LI )}^{- 1} k ( {μ}_{L + 1}^{⋀ , ml} ) & ( 6 )\end{matrix}$$

The superscript “T” indicates the transposition of a matrix or vector. “I” indicates an identity matrix.

“G” indicates Gram Matrix and is expressed as Equation (7).

$$\begin{matrix}[ Equation 7 ] & \\ G = {\{ κ ( {μ}_{l}^{⋀ , ml} , {μ}_{{l}^{′}}^{⋀ , ml} ) \}}_{l , {l}^{′} = 1}^{L} ∈ {R}^{L \times L} & ( 7 )\end{matrix}$$

“K(μ^{\hat{ },ml}_{L+1})” is expressed as Equation (8).

$$\begin{matrix}[ Equation 8 ] & \\ k ( {μ}_{L + 1}^{⋀ , ml} ) = {( κ ( {μ}_{l}^{⋀ , ml} , {μ}_{L + 1}^{⋀ , ml} ) , … , κ ( {μ}_{L}^{⋀ , ml} , {μ}_{L + 1}^{⋀ , ml} ) )}^{T} ∈ {R}^{L} & ( 8 )\end{matrix}$$

As a method for the model execution unit 192 to calculate the parameter values of the simulator model from the kernel mean μ^{\hat{ },sim}_{L+1}, a method of Kernel Herding can be used. For example, the model execution unit 192 calculates sample data θ_{L+1,j} of the parameter values of the simulation model with respect to the kernel mean μ^{\hat{ },sim}_{L+1}, using Equation (9).

$$\begin{matrix}[ Equation 9 ] & \\ {θ}_{L + 1 , j} = arg {max}_{T} {\sum }_{l = 1}^{L} {\sum }_{{j}^{′} = 1}^{m} {v}_{l} {w}_{l , j} , {k}_{θ} ( θ , {θ}_{l , {j}^{′}} ) + \frac{1}{m + 1} {\sum }_{{j}^{′} = 1}^{m} {k}_{θ} ( θ , {θ}_{l , {j}^{′}} ) ∈ {R}^{{d}_{θ}} & ( 9 )\end{matrix}$$

θ_{L+1,j}(j=1, . . . , m) indicates the jth sampling data of θ_{L+1}. Therefore, (θ_{L+1}, l, . . . , θ_{L+1,m}) indicates θ_{L+1}.

The weight w_{i,j} is calculated by kernel ABC (Kernel Approximate Bayesian Computation) with respect to {Xⁿₗ, Yⁿₗ} for obtaining the kernel mean of a posterior distribution of θₗ.

“k_{θ}” indicates a Gaussian Kernel. θ_{i,j} indicates sampling data from the jth anterior distribution with respect to the lth data set {Xⁿₗ, Yⁿₗ}.

In the case of “j=2, . . . , m”, the entire Equation (9) is applied. For the case of “j=1”, which is the initial state, the first term on the right side of Equation (9) is used. Therefore, in the case of “j=1”, Equation (10) is applied.

$$\begin{matrix}[ Equation 10 ] & \\ {θ}_{L + 1 , j} = arg {max}_{T} {\sum }_{l = 1}^{L} {\sum }_{{j}^{′} = 1}^{m} {v}_{l} {w}_{l , {j}^{′}} {k}_{θ} ( θ , {θ}_{l , {j}^{′}} ) ∈ {R}^{{d}_{θ}} & ( 10 )\end{matrix}$$

As described above, the user can use θ_{L+1} for the analysis of the prediction target 910 as a result of the model execution unit 192 calculating θ_{L+1}.

Calculation of μ^{\hat{ },sim}ₗ by the model generation unit 191 will be further described.

The model generation unit 191 may calculate μ^{\hat{ },sim}ₗ, using Equation (11).

$$\begin{matrix}[ Equation 11 ] & \\ {μ}_{l}^{⋀ , sim} = {\sum }_{j = 1}^{m} {w}_{l , j} {k}_{θ} ( \cdot , {θ}_{l , j} ) ∈ H & ( 11 )\end{matrix}$$

Each θ_{1,j} shows a sample of parameter values following the anterior distribution π(θ). m indicates the number of the samples. Here, j is an index that identifies each individual sample.

The “⋅” in the brackets indicates that the variable of the function in the RKHS space is not limited to a particular variable.

The l in Equation (11) may be read as L+1, and the model execution unit 192 may calculate μ^{\hat{ },sim}_{L+1}, using Equation (11).

Next, calculation of μ^{\hat{ },ml}ₗ by the model generation unit 191 will be further described.

Here, as an example of the case where the machine learning model of the machine learning device 20 is a parametric model, a case is assumed where the machine learning device 20 performs machine learning using a Bayesian neural network having several hidden layers. The parametric model referred to here is a model having parameters (here, learning parameters).

In this case, the model generation unit 191 may calculate μ^{\hat{ },ml}ₗ on the basis of Equation (12).

$$\begin{matrix}[ Equation 12 ] & \\ {μ}_{l}^{⋀ , ml} = {\sum }_{j = 1}^{m} {k}_{ξ} ( \cdot , {ξ}_{l , j} ) ∈ H & ( 12 )\end{matrix}$$

The posterior distribution ξₗ for “l=1, . . . , L” is an element of R^{dξ} and can be obtained using the Markov Chain Monte Carlo (MCMC) method or a variation thereof m indicates the number of parameter samples. “J=1, . . . , m” is used as an index to identify each individual parameter sample.

The Gaussian Like Kernel of the function μ^{\hat{ },ml}ₗ(μ^{\hat{ },ml}ₗ is an element of H) is taken as shown in Equation (13).

$$\begin{matrix}[ Equation 13 ] & \\ \begin{matrix}κ ( {μ}_{l}^{⋀ , ml} , {μ}_{{l}^{′}}^{⋀ , ml} ) = exp \{ - {( \frac{1}{2 {σ}_{μ}^{2}} ‖ ) {μ}_{l}^{⋀ , ml} - {μ}_{{l}^{′}}^{⋀ , ml} ‖}_{H}^{2} \} ∈ H \\ = exp \{ - \frac{1}{2 {σ}_{μ}^{2}} ( 1 - 〈 {μ}_{l}^{⋀ , ml} , {μ}_{{l}^{′}}^{⋀ , ml} 〉 ) \} \\ = exp \{ - \frac{1}{{σ}_{μ}^{2}} ( 1 - {\sum }_{j = 1}^{m} {\sum }_{{j}^{′} = 1}^{{m}^{′}} {k}_{ξ} ( {ξ}_{l , j} , {ζ}_{{l}^{′} , {j}^{′}} ) ) \}\end{matrix} & ( 13 )\end{matrix}$$

The constant σ_{μ} indicates the width of the Gaussian Like Kernel κ, where “σ_{μ>}0”.

<⋅,⋅> indicates the inner product.

The Gaussian Kernel of ξ is taken as shown in Equation (14).

$$\begin{matrix}[ Equation 14 ] & \\ {k}_{ξ} ( {ξ}_{l , j} , {ξ}_{{l}^{′} , {j}^{′}} ) = exp \{ - \frac{1}{2 {σ}_{ξ}^{2}} {‖ {ξ}_{l , j} - {ξ}_{{l}^{′} , {j}^{′}} ‖}^{2} \} ∈ R & ( 14 )\end{matrix}$$

The constant σ_{ξ} indicates the width of the Gaussian Kernel k_{ξ}, where “σ_{ξ}>0”.

While k_{ξ}(⋅, ξ_{i,j}) in Equation (12) cannot be calculated directly, by taking the inner product, the calculation becomes possible as follows. “<k(⋅, ξ̅₁, k(⋅, ξ̅₂)>=k(ξ̅₁,ξ̅₂)”. In the case of k_{ξ̅}(⋅, ξ̅_{1,j}) in Equation (12), it becomes k_{ξ}(ξ_{i, j}, ξ_{i′,j′}) in Equation (14), which makes the calculation possible.

The l in Equation (12) may be read as L+1, and the model execution unit 192 may calculate μ^{\hat{ },ml}_{L+1}, using Equation (12).

In this way, even in the case where prediction data cannot be obtained by the machine learning device 20, the parameter values of the simulation model can still be calculated by calculating the kernel mean μ^{\hat{ },ml}ₗ of the machine learning model by the model generation unit 191 and the model execution unit 192.

Meanwhile, as an example of the case where the machine learning model of the machine learning device 20 is a non-parametric model, a case is assumed where the machine learning device 20 performs machine learning using Gaussian process regression (GPR). The non-parametric model referred to here is a model not having parameters (here, learning parameters).

Gaussian process regression is equivalent to a Bayesian neural network having a single hidden layer and an infinite number of nodes.

As a result of Gaussian process regression, the mean of the anterior distribution shown in Equation (15) is obtained.

$$\begin{matrix}[ Equation 15 ] & \\ y = {μ}_{Y \vert X , l}^{⋀} = {\sum }_{i = 1}^{n} {u}_{l , i} {k}_{x} ( x , {X}_{l , i} ) ∈ H & ( 15 )\end{matrix}$$

u_{l,i} is calculated using a gram matrix of kernel kₓ. It is clear that Equation (15) holds because of the equivalence between Gaussian process regression and Kernel ridge regression.

Using μ^{\hat{ }}_{Y|X,1}, Y^{\hat{ }}_{l,n+1} is calculated as shown in Equation (16).

$$\begin{matrix}[ Equation 16 ] & \\ {Y}_{l , n + 1}^{⋀} = {μ}_{Y \vert X , l}^{⋀} ( {X}_{l , n + 1} ) & ( 16 )\end{matrix}$$

In the case of a parametric model, the parameter ξₗ is an input, whereas Xⁿₗ is an input in the case of a nonparametric model. Therefore, in a parametric model, the machine learning parameter ξ is converted to the simulator parameter θ, whereas in a non-parametric model, the input X is converted to the simulator parameter θ.

Therefore, the model execution unit 192 can obtain the parameter values of the simulator model without the need for obtaining the prediction result of the machine learning device 20.

Here, the Gaussian Like Kernel κ of the function μ^{\hat{ },ml}ₗ is taken as shown in Equation (17).

$$\begin{matrix}[ Equation 17 ] & \\ K ( {μ}_{l}^{⋀ , ml} , {μ}_{{l}^{′}}^{⋀ , ml} ) = exp \{ - \frac{1}{{σ}_{μ}^{2}} ( 1 - {\sum }_{i = 1}^{n} {\sum }_{{i}^{′} = 1}^{{n}^{′}} {u}_{l , i} {u}_{{l}^{′} , i} {k}_{x} ( {X}_{l , i} , {X}_{{l}^{′} , {i}^{′}} ) ) \} ∈ H & ( 17 )\end{matrix}$$

Also, the Gaussian Kernel of x is taken as shown in Equation (18).

$$\begin{matrix}[ Equation 18 ] & \\ {k}_{x} ( {X}_{l , i} , {X}_{{l}^{′} , {i}^{′}} ) = exp \{ - \frac{1}{2 {σ}_{x}^{2}} {‖ {X}_{l , i} - {X}_{{l}^{′} , {i}^{′}} ‖}^{2} \} ∈ R & ( 18 )\end{matrix}$$

The constant σₓ indicates the width of the kernel kₓ, where “σₓ>0”.

Next, an example of a situation to which the prediction system 1 is applied will be described.

The prediction system 1 can be applied to, for example, prediction of the required length of time on a factory production line.

FIG. 3 is a diagram showing an example of a production line that serves as a target of the prediction system 1. In the example of FIG. 3, an assembly device and an inspection device are installed on the production line.

The assembly device assembles four components, an upper component, a lower component, and two screws, to produce a product. The product assembled by the assembly device is transported into the inspection device. The inspection device inspects when four of the products have been transported thereinto.

In this assembly process, the production amount of the product per unit time is defined as data X, and the shipping time of X products (value of data X) is defined as data Y. In addition, the number of parameters in the simulation model of the simulator device 10 is two, the working time of the assembly device (the length of time required for the assembly process) is θₗ, and the working time of the inspection device (the length of time required for the inspection process) is θ₂.

It is assumed that, as the number of products to be produced increases in this process, the load increases and the length of time that elapses in each process increases significantly. Specifically, if the value of X exceeds 110, it takes time for assembly and inspection, and the values of both θₗ and θ₂ become large.

By predicting the shipping time of this production line by the machine learning device 20, the user can confirm whether or not the production line is operating appropriately. Moreover, by calculating the values of the parameters θₗ, θ₂ of the simulation model by the model generation device 30, the user can use the parameter values calculated by the model generation device 30 for analyzing the production line, for example analyzing where the bottleneck of the shipping time is.

The parameter values calculated by the model generation device 30 are not limited to the length of time required for each process described above, and may be various parameter values that can affect the prediction of the machine learning device 20. For example, in the case of a production line that is affected by the state of the surrounding environment such as weather or temperature, the model generation device 30 may calculate the weather or temperature, or a combination thereof as parameter values in addition to or instead of the length of time required for each process.

However, the application target of the prediction system 1 is not particularly limited. For example, the prediction system 1 may be applied to a physical distribution system of a delivery company or the like. Alternatively, the prediction system 1 may be applied to predicting the flow of people, such as when guiding people safely and efficiently at a venue where people gather, such as a fireworks display.

In the above description, the case of so-called distribution-distribution regression, which is illustrated by the distribution using sample data in both the machine learning model and the simulation model, has been described as an example. However, the application scope of the prediction system 1 is not limited to this example.

With use of a linear kernel as the kernel in the RKHS space, the kernel mean is the mean value of the distribution. Therefore, even when either one or both of the machine learning model and the simulation model are indicated by points, the prediction system 1 can be applied in a manner similar to that described above.

That is to say, the model generation unit 191 may calculate as a bridge model the function in the RKHS space that receives an input of the distribution of a function indicating the machine learning model and outputs the distribution of the function of the simulation model.

Alternatively, the model generation unit 191 may calculate as a bridge model the function in the RKHS space that receives an input of the distribution of a function indicating the machine learning model and outputs the points indicating the function of the simulation model.

Alternatively, the model generation unit 191 may calculate as a bridge model the function in the RKHS space that receives an input of points indicating a function that indicates the machine learning model and outputs the distribution of the function of the simulation model.

Alternatively, the model generation unit 191 may calculate as a bridge model the function in the RKHS space that receives an input of points indicating a function that indicates the machine learning model and outputs the points indicating the function of the simulation model.

By indicating either one or both of the machine learning model and the simulation model by points, the calculation cost of the model generation device 30 can be made comparatively low. In this respect, the model generation device 30 can calculate the parameter values of the simulation model relatively quickly.

As described above, the prediction system 1 can be applied not only in the case of distribution-distribution regression, but also in those cases of distribution-point regression, point-distribution regression, and point-point regression.

Alternatively, in the case where the machine learning model is a non-parametric model, both input data to a simulation model and the simulation model may be represented by distributions or points.

That is to say, the model generation unit 191 may calculate as a bridge model the function in the RKHS space that receives input of the distribution of samples input to the simulation model and outputs the distribution of the function of the simulation model.

Alternatively, the model generation unit 191 may calculate as a bridge model the function in the RKHS space that receives input of the points indicating samples input to the simulation model and outputs the distribution of the function of the simulation model.

Alternatively, the model generation unit 191 may calculate as a bridge model the function in the RKHS space that receives input of the distribution of samples input to the simulation model and outputs the points indicating the function of the simulation model.

Alternatively, the model generation unit 191 may calculate as a bridge model the function in the RKHS space that receives input of the points indicating samples input to the simulation model and outputs the points indicating the function of the simulation model.

By indicating either one or both of the input data to a simulation model and the simulation model by points, the calculation cost of the model generation device 30 can be made comparatively low. In this respect, the model generation device 30 can calculate the parameter values of the simulation model relatively quickly.

As described above, the prediction system 1 can be applied not only in the case of distribution-distribution regression, but also in those cases of distribution-point regression, point-distribution regression, and point-point regression.

As described above, the model generation unit 191 generates a bridge model indicating a relationship between: parameters included in the simulation model indicating the relationship between prediction data to be input to the simulation model, and prediction result based on the prediction data; and the prediction data.

According to the model generation device 30, when predicting the behavior or state of the prediction target 910, the parameter values of the simulation model can be obtained without the need for executing the simulation model. In this respect, according to the model generation device 30, data that can be used for analyzing an analysis target can be obtained in a comparatively short period of time.

Moreover, the model generation unit 191 generates as a bridge model the function in the RKHS space that receives input of the distribution of the prediction data input to the simulation model and outputs the distribution of the function indicating the simulation model.

According to the model generation unit 191, the distribution of parameter values of the simulation model can be calculated, and in this respect, the parameter values of the simulation model can be calculated at a high level of accuracy.

Moreover, the model generation unit 191 generates as a bridge model the function in the RKHS space that receives input of the distribution of the prediction data input to the simulation model and outputs the points indicating the function that indicates the simulation model.

According to the model generation unit 191, since the function indicating the simulation model is indicated by a point, the calculation cost can be made comparatively low.

Moreover, the model generation unit 191 generates as a bridge model the function in the RKHS space that receives input of the points indicating the prediction data input to the simulation model and outputs the distribution of the function indicating the simulation model.

According to the model generation unit 191, since the prediction data input to the simulation model is indicated by a point, the calculation cost can be made comparatively low.

Moreover, the model generation unit 191 generates as a bridge model the function in the RKHS space that receives input of the point indicating the prediction data input to the simulation model and outputs the point indicating the function that indicates the simulation model.

According to the model generation unit 191, since the prediction data input to the simulation model and the function indicating the simulation model are both indicated by points, the calculation cost can be made comparatively low.

Moreover, the model generation unit 191 generates as a bridge model the function in the RKHS space that outputs the kernel mean that indicates the simulation model.

According to the model generation device 30, a technique such as kernel mean can be used as part of bridge model generation, and the bridge model generation process can be designed comparatively easily.

Moreover, the model execution unit 192 calculates parameter values of the simulation model on the basis of the kernel mean that indicates the simulation model.

The user can use these parameter values for the analysis of the prediction target 910.

Moreover, the simulator device 10 sets the parameter values of the simulation model, using a data set in which the prediction data input to the simulation model and the prediction result for the prediction data are associated with each other.

According to the prediction system 1, the model generation device 30 generates a bridge model on the basis of the parameters set by the simulator device 10. The model generation device 30 estimating the parameter values of the simulation model using this bridge model enables the user to use the estimated parameter values for the analysis of the prediction target 910.

Moreover, the model execution unit 192 applies to new prediction data, a bridge model indicating a relationship between: parameters included in the simulation model indicating the relationship between prediction data to be input to the simulation model, and the prediction result for the prediction data; and the prediction data, to thereby calculate the parameters of the simulation model regarding the new prediction data.

The user can use the parameter values of the simulation model regarding the new prediction data for the analysis of the prediction target 910.

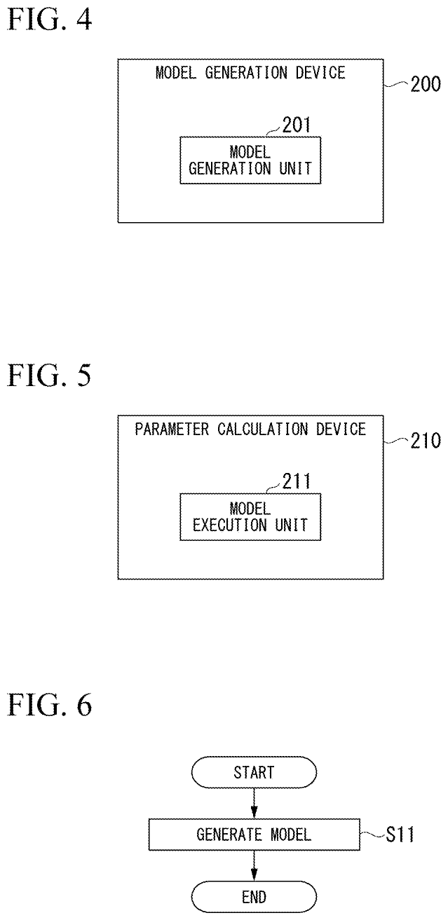

Next, a configuration example of an example embodiment will be described, with reference to FIG. 4 to FIG. 7.

FIG. 4 is a diagram showing a configuration example of a model generation device according to an example embodiment. A model generation device 200 shown in FIG. 4 includes a model generation unit 201.

In this configuration, the model generation unit 201 generates a second model indicating a relationship between: parameters included in a first model, which indicates a relationship between samples and labels of the samples; and the samples.

According to the model generation device 200, when predicting the behavior or state of the prediction target 910, the parameter values of the simulation model can be obtained without the need for executing the simulation model. In this respect, according to the model generation device 200, data that can be used for analyzing an analysis target can be obtained in a comparatively short period of time.

FIG. 5 is a diagram showing an example of a configuration of a parameter calculation device according to an example embodiment. A parameter calculation device 210 shown in FIG. 5 includes a model execution unit 211.

In this configuration, the model execution unit 211 calculates parameters of the first model regarding given samples by applying, to the given samples, a second model indicating a relationship between: parameters included in the first model, which indicates the relationship between samples and labels of the samples; and the samples.

The user can use the parameter values of the first model regarding the given samples for the analysis of a prediction target.

FIG. 6 is a diagram showing an example of processing in a model generation method according to an example embodiment.

The model generation method shown in FIG. 6 includes Step S11. Step S11 is a step of generating a second model indicating a relationship between: parameters included in a first model, which indicates the relationship between samples and labels of the samples; and the samples.

According to the model generation method shown in FIG. 6, when predicting the behavior or state of a prediction target, the parameter values of the simulation model can be obtained without the need for executing the simulation model.

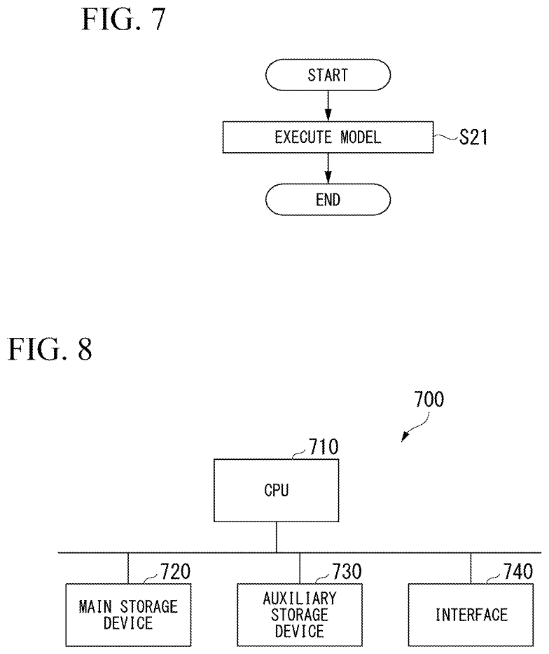

FIG. 7 is a diagram showing an example of processing in the parameter calculation method according to an example embodiment.

The parameter calculation method shown in FIG. 7 includes Step S21. Step S21 is a step of calculating parameters of the first model regarding given samples by applying, to the given samples, a second model indicating a relationship between: parameters included in the first model, which indicates the relationship between samples and labels of the samples; and the samples.

According to the parameter calculation method shown in FIG. 7, the user can use the parameter values of the first model regarding the given samples for the analysis of a prediction target.

In the example embodiments described above, the description has been made using a simulation; however, the parameter values may actually represent the actual operation (or state) of a prediction target, instead of the simulation. Alternatively, the operation of the prediction target may be controlled according to the calculated parameter values. In such a case, the model generation device sets the calculated parameter values as the parameter values of a control device that controls the processing (operation) of the prediction target. The control device controls the prediction target according to the parameter values. For example, the model generation device functions as a device that determines the goods to be delivered to be loaded on the truck according to the calculated parameter values. Alternatively, the model generation device functions as a device that determines the processing amount to be processed by each device on the production line according to the calculated parameter values, and controls the operation of each device according to the determined processing amount. That is to say, the model generation device functions as a device that controls the processing (operation) of the prediction target according to the calculated parameter values.

FIG. 8 is a schematic block diagram showing a configuration of a computer according to at least one example embodiment.

In the configuration shown in FIG. 8, a computer 700 includes a CPU 710, a main storage device 720, an auxiliary storage device 730, and an interface 740.

One or more of the model generation device 30, the model generation device 200, and the parameter calculation device 210 may be implemented in the computer 700. In such a case, operations of the respective processing units described above are stored in the auxiliary storage device 730 in the form of program. The CPU 710 reads the program from the auxiliary storage device 730, loads it on the main storage device 720, and executes the processing described above according to the program. Moreover, the CPU 710 secures, according to the program, storage regions corresponding to the respective storage units mentioned above, in the main storage device 720. Communication between each device and another device is executed by the interface 740 having a communication function and communicating according to the control of the CPU 710.

In the case where the model generation device 30 is implemented in the computer 700, operations of the control unit 190 and each unit thereof are stored in the auxiliary storage device 730 in the form of program. The CPU 710 reads the program from the auxiliary storage device 730, loads it on the main storage device 720, and executes the processing described above according to the program.

Moreover, the CPU 710 secures, according to the program, a storage region corresponding to the storage unit 180 mentioned above, in the main storage device 720. Communication performed by the communication unit 110 is executed by the interface 740 having a communication function and communicating according to the control of the CPU 710. The processing performed by the display unit 120 is executed by the interface 740 including a display device and displaying images according to the control of the CPU 710. The processing performed by the operation input unit 130 is executed by the interface 740 including an input device, accepting user operations, and outputting signals indicating the performed user operations to the CPU 710.

In the case where the model generation device 200 is implemented in the computer 700, operations of the model generation unit 201 are stored in the auxiliary storage device 730 in the form of program. The CPU 710 reads the program from the auxiliary storage device 730, loads it on the main storage device 720, and executes the processing described above according to the program.

In the case where the parameter calculation device 210 is implemented in the computer 700, operations of the model execution unit 211 are stored in the auxiliary storage device 730 in the form of program. The CPU 710 reads the program from the auxiliary storage device 730, loads it on the main storage device 720, and executes the processing described above according to the program.

It should be noted that a program for realizing all or part of the functions of the model generation device 30, the model generation device 200, or the parameter calculation device 210 may be recorded on a computer-readable recording medium, and the program recorded on the recording medium may be read into and executed on a computer system, to thereby perform the processing of each unit. The “computer system” referred to here includes an operating system and hardware such as peripheral devices.

Moreover, the “computer-readable recording medium” referred to here refers to a portable medium such as a flexible disk, a magnetic optical disk, a ROM (Read Only Memory), and a CD-ROM (Compact Disc Read Only Memory), or a storage device such as a hard disk built in a computer system. The above program may be a program for realizing a part of the functions described above, and may be a program capable of realizing the functions described above in combination with a program already recorded in a computer system.

The example embodiments of the present invention have been described in detail with reference to the drawings. However, the specific configuration of the invention is not limited to the example embodiments, and may include design changes and so forth that do not depart from the scope of the present invention.

The whole or part of the example embodiments disclosed above can be described as, but not limited to, the following supplementary notes.

### (Supplementary Note 1)

A model generation device comprising:

a model generation means for generating a second model indicating a relationship between a parameter included in a first model and a sample, the first model indicating a relationship between the sample and a label of the sample.

### (Supplementary Note 2)

The model generation device according to supplementary note 1, wherein the model generation means generates the second model that receives input of a distribution of the sample and outputs a distribution of a function indicating the first model.

### (Supplementary Note 3)

The model generation device according to supplementary note 1, wherein the model generation means generates the second model that receives input of a distribution of the sample and outputs a point indicating a function indicating the first model.

### (Supplementary Note 4)

The model generation device according to supplementary note 1, wherein the model generation means generates the second model that receives input of a point indicating the sample and outputs a distribution of a function indicating the first model.

### (Supplementary Note 5)

The model generation device according to supplementary note 1, wherein the model generation means generates the second model that receives input of a point indicating the sample and outputs a point indicating a function indicating the first model.

### (Supplementary Note 6)

The model generation device according to any one of supplementary notes 1 to 5, wherein the model generation means generates, as the second model, a function of an RKHS space that receives input of a kernel mean indicating the sample and outputs a kernel mean indicating the first model.

### (Supplementary Note 7)

The model generation device according to any one of supplementary notes 1 to 5, wherein the model generation means generates the second model that outputs a kernel mean indicating the first model.

### (Supplementary Note 8)

The model generation device according to supplementary note 6 or 7, further comprising:

a model execution means for calculating a value of the parameter of the first model based on the kernel mean indicating the first model.

### (Supplementary Note 9)

A system comprising:

the model generation device according to supplementary note 1; and

a parameter setting means for setting the parameter included in the first model, using a data set in which the sample and the label of the sample are associated with each other.

### (Supplementary Note 10)

A parameter calculation device comprising:

a model execution means for calculating a parameter of a first model regarding a given sample by applying a second model to the given sample, the first model indicating a relationship between a sample and a label of the sample, the second model indicating a relationship between a parameter included in the first model and the sample.

### (Supplementary Note 11)

A model generation method executed by a computer, comprising:

generating a second model indicating a relationship between a parameter included in a first model and a sample, the first model indicating a relationship between the sample and a label of the sample.

### (Supplementary Note 12)

A parameter calculation method execute by a computer, comprising:

a model execution means for calculating a parameter of a first model regarding a given sample by applying a second model to the given sample, the first model indicating a relationship between a sample and a label of the sample, the second model indicating a relationship between a parameter included in the first model and the sample.

### (Supplementary Note 13)

A recording medium storing a program for causing a computer to execute a function of:

generating a second model indicating a relationship between a parameter included in a first model and a sample, the first model indicating a relationship between the sample and a label of the sample.

### (Supplementary Note 14)

A recording medium storing a program for causing a computer to execute a function of:

calculating a parameter of a first model regarding a given sample by applying a second model to the given sample, the first model indicating a relationship between a sample and a label of the sample, the second model indicating a relationship between a parameter included in the first model and the sample.

This application is based upon and claims the benefit of priority from Japanese patent application No. 2019-096326, filed May 22, 2019, the disclosure of which is incorporated herein in its entirety by reference.

### INDUSTRIAL APPLICABILITY

The present invention may be applied to a model generation device, a system, a parameter calculation device, a model generation method, a parameter calculation method, and a recording medium.

### REFERENCE SYMBOLS

1 Prediction system
10 Simulator device
20 Machine learning device
30,200 Model generation device
110 Communication unit (communication means)
120 Display unit (display means)
130 Operation input unit (operation input means)
180 Storage unit (storage means)
190 Control unit (control means)
191, 201 Model generation unit (model generation means)
192, 211 Model execution unit (model execution means)
210 Parameter calculation device

What is claimed is:

1. A model generation device comprising:
at least one memory configured to store the instructions; and
at least one processor configured to execute the instructions to:
generate a second model indicating a relationship between a parameter included in a first model and a sample, the first model indicating a relationship between the sample and a label of the sample.

2. The model generation device according to claim 1, wherein the at least one processor is configured to execute the instructions to generate the second model that receives input of a distribution of the sample and outputs a distribution of a function indicating the first model.

3. The model generation device according to claim 1, wherein the at least one processor is configured to execute the instructions to generate the second model that receives input of a distribution of the sample and outputs a point indicating a function indicating the first model.

4. The model generation device according to claim 1, wherein the at least one processor is configured to execute the instructions to generate the second model that receives input of a point indicating the sample and outputs a distribution of a function indicating the first model.

5. The model generation device according to claim 1, wherein the at least one processor is configured to execute the instructions to generate the second model that receives input of a point indicating the sample and outputs a point indicating a function indicating the first model.

6. The model generation device according to claim 1, wherein the at least one processor is configured to execute the instructions to generate, as the second model, a function of a reproducing Kernel Hilbert space (RKHS) that receives input of a kernel mean indicating the sample and outputs a kernel mean indicating the first model.

7. The model generation device according to claim 1, wherein the at least one processor is configured to execute the instructions to generate the second model that outputs a kernel mean indicating the first model.

8. The model generation device according to claim 6, wherein the at least one processor is configured to execute the instructions to calculate a value of the parameter of the first model based on the kernel mean indicating the first model.

9. A system comprising:
the model generation device according to claim 1,
wherein the at least one processor is configured to execute the instructions to set the parameter included in the first model, using a data set in which the sample and the label of the sample are associated with each other.

10. A parameter calculation device comprising:
at least one memory configured to store the instructions; and
at least one processor configured to execute the instructions to:
calculate a parameter of a first model regarding a given sample by applying a second model to the given sample, the first model indicating a relationship between a sample and a label of the sample, the second model indicating a relationship between a parameter included in the first model and the sample.

11. A model generation method executed by a computer, comprising:
generating a second model indicating a relationship between a parameter included in a first model and a sample, the first model indicating a relationship between the sample and a label of the sample.

12-14. (canceled)
